(19) United States
(12) Patent Application Publication
(10) Pub. No.: US 2013/0240021 A1
(43) Pub. Date: Sep. 19, 2013

(54) LAMINATED FLAME RESISTANT SHEETS

(71) Applicants: MINFANG MU, Shanghai (CN); Qiuju Wu, Shanghai (CN); Philip L. Boydell, Challex (FR); Yves M. Trouilhet, Vesenaz (CH)

(72) Inventors: MINFANG MU, Shanghai (CN); Qiuju Wu, Shanghai (CN); Philip L. Boydell, Challex (FR); Yves M. Trouilhet, Vesenaz (CH)

(73) Assignee: E I DU PONT DE NEMOURS AND COMPANY, Wilmington, DE (US)

(21) Appl. No.: 13/608,088

(22) Filed: Sep. 10, 2012

(30) Foreign Application Priority Data
Sep. 21, 2011 (CN) 201110289691.8

(51) Int. Cl. H01L 31/048; B32B 27/06; B32B 3/26

(52) U.S. Cl. CPC H01L 31/0487; B32B 3/266; B32B 27/06
USPC 136/251; 428/138; 136/259

(57) ABSTRACT

Disclosed herein is a laminated flame resistant sheet comprising a first and a second polymeric film layer and a perforated flame resistant sheet layer laminated between the first and the second polymeric film layer, wherein, the perforated flame resistant sheet layer is formed of a sheet that is not ignitable following UL 94 horizontal burning test and comprises multiple apertures throughout, and wherein each of the apertures has an average diameter of about 0.1-8 mm and are spaced about 1-50 mm apart from adjacent apertures. Further disclosed herein is an article, such as a solar cell module, comprising the laminated flame resistant sheet.

### FIELD OF DISCLOSURE

The present disclosure is related to laminated flame resistant sheets and articles comprising the same.

### BACKGROUND

Photovoltaic (PV) modules (also known as solar cell modules) are used to produce electrical energy from sunlight, offering an environmentally friendly alternative to traditional methods of electricity generation. Such modules are based on a variety of semiconductor cell systems that can absorb light and convert it into electrical energy and are typically categorized into one of two types of modules based on the light absorbing material used, i.e., bulk or wafer-based modules and thin film modules.

Generally, individual cells are electrically connected in an array to form a module, and such an array of modules can be connected together in a single installation to provide a desired amount of electricity. When the light absorbing semiconductor material in each cell, and the electrical components used to transfer the electrical energy produced by the cells, are suitably protected from the environment, photovoltaic modules can last 25, 30, and even 40 or more years without significant degradation in performance. In a typical photovoltaic module construction, the solar cell layer is sandwiched between two encapsulant layers, which layers are further sandwiched between frontsheet and backsheet layers. It is desirable that the frontsheets and backsheets have good weather resistance, UV resistance, moisture barrier properties, and electrical insulating properties.

Solar cell modules are often times being installed on roof tops and, more recently, are being used as parts of building structures, such as the building envelope, roofs, skylights, or facades. Accordingly, there is a need to provide solar cell modules with improved flame resistance.

Inorganic materials such as mica, vermiculite, and ceramic fibers are well-known flame resistant materials and they have been made into fire proof or fire retardant sheets or plates. However, the inclusion of such flame resistant sheets or plates in laminated backsheets can compromise the bonding integrity of the laminated backsheets and thereby reduce the durability of the solar cell modules. Therefore, a need to provide a laminated flame resistant backsheet structure that is useful in solar cell modules still exists.

### SUMMARY

The purpose of this invention is to provide a laminated flame resistant sheet having internal bonding integrity, and where the laminated flame resistant sheet comprises a first and a second polymeric film layer and a perforated flame resistant sheet layer laminated between the first and the second polymeric film layers, wherein, the perforated flame resistant sheet layer is formed of a sheet that is not ignitable following the UL 94 horizontal burning test and comprises multiple apertures throughout, and wherein each of the apertures has an average diameter of 0.1-8 mm and are spaced 1-50 mm apart from adjacent apertures.

In one embodiment of the laminated flame resistant sheet, the perforated flame resistant sheet layer is formed of a composition comprising 40 wt % or more (based on the total weight of the composition) of inorganic particulates selected from the group consisting of crystallized mineral silicate platelets, ceramic fibers, alumina powders, gibbsite powders, asbestos fibers, glass fibers, and combinations of two or more thereof. Or, the inorganic particulates may be selected from the group consisting of crystallized mineral silicate platelets, preferably from the group consisting of particles of mica, vermiculite, calcined clay, silica, talc, wollastonite, and combinations of two or more thereof; and more preferably from particles of mica. Or, the inorganic particulates may be selected from ceramic fibers.

In a further embodiment of the laminated flame resistant sheet, the composition that forms the perforated flame resistant sheet layer may comprise 60 wt % or more, or preferably 80 wt % or more (based on the total weight of the composition) of the inorganic particulates.

In a yet further embodiment of the laminated flame resistant sheet, each of the apertures may have an average diameter of 0.3-5 mm, or 0.3-3 mm and are spaced 1-30 mm, or 2-25 mm apart.

In a yet further embodiment of the laminated flame resistant sheet, each of the first and second polymeric film layers is independently formed of a composition comprising a polymeric material selected from the groups consisting of fluoropolymers, polyesters, polycarbonates, polyolefins, ethylene copolymers, polyvinyl butyrals, norbornenes, polystyrenes, styrene-acrylate copolymers, acrylonitrile-styrene copolymers, polyacrylates, polyethersulfones, polysulfones, polyamides, polyurethanes, acrylics, cellulose acetates, cellulose triacetates, cellophanes, polyvinyl chlorides, vinylidene chloride copolymers, epoxy, and combinations of two or more thereof. Or, each of the first and second polymeric film layers may be independently formed of a composition comprising a fluoropolymer or a polyester. In such embodiments, the fluoropolymer may be selected from the group consisting of homopolymers and copolymers of vinyl fluorides (VF), vinylidene fluorides (VDF), tetrafluoroethylenes (TFE), hexafluoropropylenes (HFP), chlorotrifluoroethlyenes (CTFE), and combinations of two or more thereof, preferably from the group consisting of polyvinyl fluorides (PVF), polyvinylidene fluorides (PVDF), ethylene chlorotrifluoroethlyene copolymers (ECTFE), ethylene tetrafluoroethylene copolymers (ETFE), and combinations of two or more thereof, more preferably from the group consisting of polyvinyl fluorides (PVF), polyvinylidene fluorides (PVDF), polytetrafluoroethylenes, ethylene-tetrafluoroethylene copolymers (ETFE), ethylene chlorotrifluoroethlyenes copolymers (ECTFE), and combinations of two or more thereof, and yet more preferably from PVF. Also, the polyester may be selected from the group consisting of polyethylene terephthalate (PET), polybutylene terephthalate (PBT), polyethylene trimethylene terephthalate (PTT), polyethylene naphthalates (PEN), and combinations of two or more thereof, preferably from PET.

In a yet further embodiment of the laminated flame resistant sheet, the first polymeric film layer is formed of a composition comprising a fluoropolymer and the second polymeric film layer is formed of a composition comprising a polyester, and wherein the fluoropolymer is preferably PVF and the polyester is preferably PET.

In a yet further embodiment of the laminated flame resistant sheet, the sheet further comprises a first adhesive layer disposed between the perforated flame resistant sheet layer and the first polymeric film layer and/or a second adhesive layer disposed between the perforated flame resistant sheet layer and the second polymeric film layer. In such embodiments, each of first and second adhesive layers may be independently formed of an adhesive material selected from the group consisting of reactive adhesives and non-reactive adhesives. Preferably the reactive adhesives are selected from the group consisting of polyurethanes, acrylics, epoxy, polyimides, silicones, and combinations of two or more thereof, and the non-reactive adhesives are preferably selected from polyethylenes, polyesters, and combinations thereof. Or, the first and second adhesive layer may be independently formed of an adhesive material selected from polyurethanes and ethylene copolymers.

In a yet further embodiment of the laminated flame resistant sheet, the sheet further comprises other additional film or sheet layers.

Further provided herein is an article comprising the laminated flame resistant sheet described above. The article may be selected from the group consisting of solar cell modules, roofs, building envelops, skylights, facades, and packaging films.

Yet further provided herein is a solar cell module comprising a solar cell layer formed of one or a plurality of solar cells, a back encapsulant layer laminated to a back side of the solar cell layer, and a backsheet laminated to a backside of the back encapsulant layer, wherein the backsheet is formed of the laminated flame resistant sheet described above.

In accordance with the present disclosure, when a range is given with two particular end points, it is understood that the range includes any value that is within the two particular end points and any value that is equal to or about equal to any of the two end points.

### DRAWINGS

FIG. 1 is a not-to-scale cross-sectional view of one embodiment of the laminated flame resistant sheet disclosed herein.

FIG. 2 is a not-to-scale top view of a perforated flame resistant sheet layer of the laminated flame resistant sheet disclosed herein.

FIG. 3 is a not-to-scale cross-sectional view of a further embodiment of the laminated flame resistant sheet disclosed herein.

FIG. 4 is a not-to-scale cross-sectional view of one embodiment of the solar cell modules disclosed herein.

### DETAILED DESCRIPTION

Referring to FIG. 1, disclosed herein is a laminated flame resistant sheet (10) comprising a perforated flame resistant sheet layer (11), which has its first surface (11a) bonded to a first polymeric film layer (12) and its second surface (11b) bonded to a second polymeric film layer (13). By “laminated”, it is meant that the two film or sheet layers are bonded together directly or indirectly. In those embodiments wherein the two film or sheet layers are bonded together indirectly, there may be adhesive or other layers positioned and bonded between the two layers.

In accordance with the present disclosure, the perforated flame resistant sheet layer (11) is formed of a sheet that is not ignitable following UL 94 horizontal burning test and comprises multiple apertures (14) throughout, wherein each of the apertures (14) has an average diameter of about 0.1-8 mm, or about 0.3-5 mm, or about 0.3-3 mm and are spaced about 1-50 mm, or about 1-30 mm, or about 2-25 mm apart. FIG. 2 shows a top view of the perforated flame resistant layer (11). Also in accordance with the present disclosure, the perforated flame resistant sheet layer (11) may be formed of a composition comprising about 40 wt % or more, or about 60 wt % or more, or about 80 wt % or more (based on the total weight of the composition) of inorganic particulates selected from crystallized mineral silicate platelets, ceramic fibers, alumina powders, gibbsite powders, asbestos fibers, glass fibers, and combinations of two or more thereof. In one embodiment, the inorganic particulates used herein are selected from crystallized mineral silicate platelets and ceramic fibers.

The term “platelet” used herein refers to flat disc or generally oval shaped planar particles that are significantly longer and wider than their thickness. The crystallized mineral silicate platelets used herein may have an average diameter, length, or width of about 1-3000 μm, or about 100-2500 μm, or about 200-2000 μm and a thickness of about 0.01-100 μm, or about 0.05-50 μm, or about 0.1-30 μm. In those embodiments wherein the platelets are disc shaped, the length and width of the particles is similar, and in those embodiments wherein the platelets have a generally oval shape, the length of the particles may be about 1.5-5 times the width of the particles. The average particle diameter or length of the crystallized mineral silicate platelets may be about 20-300 times, or about 50-300 times, or about 100-300 times greater than the thickness of the platelets. In one embodiment, the crystallized mineral silicate platelets used herein have an average particle diameter of about 10-2000 μm, or about 100-1500 μm, or about 200-1000 μm and an average thickness of about 0.01-100 μm, or about 0.5-50 μm, or about 2-30 μm. If the particle size is too large, the platelets may add surface roughness to the sheets made therefrom. If the particle size is too small, the platelets may be difficult to disperse and the viscosity may be excessively high.

The crystallized mineral silicate platelets used herein may be selected from particles of mica, vermiculite, calcined clay, silica, talc, wollastonite, and combinations of two or more thereof. In one embodiment, the crystallized mineral silicate platelets used herein are selected from platelet-shaped particles of mica and vermiculite as they are inexpensive, disperse well and yield favorable electrical insulation, mechanical, and flame resistant properties.

Mica is a well-known crystallized mineral silicate available in a variety of monoclinic forms that readily separate into very thin leaves or plates. Exemplary mica useful herein include, without limitation,
phlogopite (also known as magnesium mica) represented by chemical formula K(Mg,Fe,Mn)₃(AlSi₃O₁₀)(F,OH)₂;
biotite (also known as iron mica or black mica) represented by chemical formula K(Mg,Fe)₃(AlSi₃O₁₀)(F,OH)₂;
zinnwaldite represented by chemical formula KLiFeAl(AlSi₃)O₁₀(OH,F)₂;
lepidolite (also known as lithium mica) represented by chemical formula KLi₂Al(Al,Si)₃O₁₀(F,OH)₂;
muscovite (including calcined muscovite) represented by chemical formula KAl₂(AlSi₃O₁₀)(F,OH)₂;
paragonite (also known as sodium mica) represented by chemical formula NaAl₂[(OH)₂AlSi₃O₁₀];
clintonite represented by chemical formula Ca(Mg,Al)₃(Al₃Si)O₁₀(OH)₂;
synthetic mica represented by chemical formula KMg₃(AlSi₃O₁₀)F₂.

Various mica platelets useful herein are also commercially available, e.g., from Lingshou Xingguang Mica Processing Factory (China) or Lingshou Huajing Mica Co., Ltd. (China) in the forms of powders or flakes.

Vermiculite is a natural mineral that expands with the application of heat. The platelet shaped vermiculite can be represented by chemical formula (MgFe,Al)₃(Al,Si)₄O₁₀(OH)₂₄H₂O. Suitable vermiculite platelets may also be obtained commercially from M/S. Garg Mineral & Chemicals (India) or Great Wall Mineral (China).

The ceramic fibers used herein in forming the perforated flame resistant sheet layer (11) may be continuous or may have a discrete length (e.g., chopped fibers) and may be in the form of individual fibers (e.g., straight, crimped, or rovings), yarns, or fabric (e.g., woven, knitted, or nonwoven). The ceramic fibers used herein may have an averaged diameter of about 1-25 μm, or about 1-10 μm, or about 1-5 μm, although fibers with larger or smaller diameters may also be useful. The ceramic fibers used herein may have a length up to tens of millimeters. However, if chopped, the ceramic fibers used herein may have an average length of about 3-50 mm, although longer or shorter fibers may also be useful. The ceramic fibers used herein may be sufficiently refractory to withstand heating to a temperature of 700° C. for more than 100 hours without significant embrittlement, and/or heating to a temperature of 1200° C. for at least a brief period of time (e.g., 1 minute). The ceramic fibers used herein may also contain glassy and/or crystalline phases, and may be formed using materials including, without limitation, metal oxides, metal nitrides, metal carbides, and minerals such as feldspar and aluminum silicates and combinations thereof. In one embodiment, the ceramic fibers are primarily or completely formed from metal oxides including, without limitation, alumina, alumina-silica, alumina-boria-silica, silica, zirconia, zirconia-silica, titania, titania-silica, rare earth oxides, or a combination of two or more thereof.

Suitable ceramic fibers may be obtained commercially from, e.g., 3M Company (U.S.A.) under the trade name NEXTEL™, or Hitco Carbon Composites, Inc. (U.S.A.) under the trade name REFRASIL™.

Preparing sheet structures comprising the inorganic particulates disclosed hereabove (e.g., crystallized mineral silicate platelets and/or ceramic fibers) are well-known among those skilled in the art. For example, they may be prepared by a process that is similar to the traditional paper making process, which may include mixing the inorganic particulates in an aqueous dispersion; drawing the dispersion down on a polymer film or other scrim to produce a wet film of the particulates with a thickness of, e.g., about 1 mm; and drying the wet film (e.g., overnight at room temperature followed by a second night at about 120° C.) to remove residual moisture and obtain the dry sheet having a thickness of, e.g., about 0.05-0.2 mm. In order to increase the strength, durability and handling capacity, the dry sheet also may be impregnated with binder such as a silicone resin, polyurethane or epoxy. Preferably, such binder comprises no more than 60 wt % of the dried sheet, and preferably the binder comprises no more than 40 wt % of the dried sheet, and more preferably the binder comprises no more than 20 wt % of the dried sheet. Or, alternatively, the aqueous dispersion comprising the inorganic particulates, as described above, may be drawn on an inorganic scrim or sheet (e.g., a glass fiber sheet).

Sheets comprising the inorganic particulates, which may be used herein, are also commercially available from e.g., PAMICA Group Limites (China), Xingjiang Mica Insulation Material Factory (China), Sichuan Meifeng Mica Industry Co., Ltd. (China), Isolite Insulating Products Co., Ltd. (Japan), Thermal Ceramics Inc. (U.S.A.), or YESO Insulating Products Co., Ltd. (China).

The perforated flame resistant sheet layer (11) of the laminated flame resistant sheet (10) is obtained by introducing multiple apertures (14) throughout the inorganic particulate containing sheets as obtained above. In accordance with the present disclosure, the apertures (14) may have an average diameter of about 0.1-8 mm, or about 0.3-5 mm, or about 0.3-3 mm, and each pair of adjacent apertures are positioned about 1-50 mm, or about 1-30 mm, or about 2-25 mm apart from each other.

Any suitable methods may be used in forming these apertures (14) over the inorganic particulate containing sheet structures, for example, die cutting, punch cutting, and hole drilling.

Each of the first and second polymeric film layers (12 and 13) bonded on each side (11a and 11b) of the perforated flame resistant sheet layer (11) may be independently formed of a composition comprising a polymeric material selected from fluoropolymers, polyesters, polycarbonates, polyolefins (including, e.g., polypropylene, polyethylene), ethylene copolymers (including, e.g., ethylene vinyl acetates (EVA), ethylene acrylic acid copolymers, ethylene acrylic ester copolymers, ionomers), polyvinyl butyrals, norbornenes, polystyrenes, styrene-acrylate copolymers, acrylonitrile-styrene copolymers, polyacrylates, polyethersulfones, polysulfones, polyamides, polyurethanes, acrylics, cellulose acetates, cellulose triacetates, cellophanes, polyvinyl chlorides, vinylidene chloride copolymers, epoxy, and combinations of two or more thereof. In one embodiment, each of the first and second polymeric film layers (12 and 13) may be independently formed of a composition comprising a fluoropolymer or polyester.

The fluoropolymers used herein in forming the first and/or second polymeric film layers (12 and 13) are polymers made from at least one fluorinated monomer (fluoromonomer) (i.e., wherein at least one of the monomers contains fluorine, preferably an olefinic monomer with at least one fluorine or a perfluoroalkyl group attached to a doubly-bonded carbon). The fluorinated monomer may be selected from, without limitation, tetrafluoroethylene (TFE), hexafluoropropylene (HFP), chlorotrifluoroethylene (CTFE), trifluoroethylene, hexafluoroisobutylene, perfluoroalkyl ethylene, fluorovinyl ethers, vinyl fluoride (VF), vinylidene fluoride (VF2), perfluoro-2,2-dimethyl-1,3-dioxole (PDD), perfluoro-2-methylene-4-methyl-1,3-dioxolane (PMD), perfluoro (allyl vinyl ether), and perfluoro (butenyl vinyl ether). In one embodiment, the fluoropolymers used herein are selected from homopolymers and copolymers of vinyl fluorides (VF), vinylidene fluorides (VDF), tetrafluoroethylenes (TFE), hexafluoropropylenes (HFP), chlorotrifluoroethlyenes (CTFE), and combinations of two or more thereof. In a further embodiment, the fluoropolymers used herein are selected from polyvinyl fluorides (PVF), polyvinylidene fluorides (PVDF), ethylene chlorotrifluoroethlyene copolymers (ECTFE), ethylene tetrafluoroethylene copolymers (ETFE), and combinations of two or more thereof. In a yet further embodiment, the fluoropolymers used herein are selected from PVF.

In one embodiment, the fluoropolymer films used herein in forming the first and/or second polymeric film layers (12 and 13) may consist essentially of PVF, which is a thermoplastic fluoropolymer with repeating units of —(CH₂CHF)ₙ—. PVF may be prepared by any suitable process, such as those disclosed in U.S. Pat. No. 2,419,010. In general, PVF has insufficient thermal stability for injection molding and is thus usually made into films or sheets via a solvent extrusion or casting process. In accordance with the present disclosure, the PVF film may be prepared by any suitable process, such as casting or solvent assisted extrusion. For example, U.S. Pat. No. 2,953,818 discloses an extrusion process for the preparation of films from orientable PVF and U.S. Pat. No. 3,139,470 discloses a process for preparing PVF films.

Suitable PVF films used herein in forming the first and/or second polymeric films (12 and/or 13) are more fully disclosed in U.S. Pat. No. 6,632,518. The PVF films used herein may also be obtained commercially, e.g., from E.I. du Pont de Nemours and Company (U.S.A.) (hereafter “DuPont”) under the trade name Tedlar®.

In a further embodiment, the fluoropolymer films used herein in forming the first and/or second polymeric films (12 and 13) may consist essentially of PVDF, which is a thermoplastic fluoropolymer with repeating units of —(CH₂CF₂)ₙ—. Commercially available oriented PVDF films, include, without limitation, Kynar™ PVDF films from Arkema Inc. (U.S.A.) and Denka DX films from Denka Group (Japan).

The polyesters used herein in forming the first and/or second polymeric films (12 and 13) are those polymers containing the ester functional group in their main chain. Suitable polyesters may include, without limitation, polyethylene terephthalate (PET), polybutylene terephthalate (PBT), polyethylene trimethylene terephthalate (PTT), polyethylene naphthalates (PEN), and combinations of two or more thereof. In one embodiment, the polyesters used herein are PET.

Suitable polyester films used herein in forming the first and second polymeric film layers (12 and 13) may be prepared by any suitable sheet or film forming process, such as hot-melt extrusion, blown film extrusion, casting, calendering, and the like. Suitable polyester films (e.g., PET films) are available from DuPont Teijin Films under the trade name Mylar® or Toray Plastics (U.S.A.), Inc. under the trade name Lumirror™.

The compositions forming the first and second polymeric film layers (12 and 13) may further comprise minor amounts of any additives known within the art. Such additives include, without limitation, plasticizers, processing aids, flow enhancing additives, lubricants, pigments, dyes, flame retardants, impact modifiers, nucleating agents, antiblocking agents (e.g., silica), thermal stabilizers, hindered amine light stabilizers (HALS), UV absorbers, UV stabilizers, dispersants, surfactants, chelating agents, coupling agents, adhesives, primers, reinforcement additives (e.g., glass fiber, fillers), and the like.

The thickness of each of the first and second polymeric film layers (12 and 13) is not critical and may be varied depending on the particular application. Generally, when fluoropolymer (e.g., PVF) is used, the thickness of the first or second polymeric film layer (12 or 13) may be about 2.5-254 μm, or about 5-100 μm, or about 10-50 μm; while when polyester (e.g., PET) is used, the thickness of the first or second polymeric film layer (12 or 13) may be about 10-800 μm, or about 50-500 μm, or about 70-250 μm.

In one embodiment of the laminated flame resistant sheet (10), the first polymeric film layer (12) and the second polymeric film layer (13) are each formed of a polyester (e.g., PET). In a further embodiment of the laminated flame resistant sheet (10), the first polymeric film layer (12) and the second polymeric film layer (13) are each formed of a fluoropolymer (e.g., PVF). In a yet further embodiment of the laminated flame resistant sheet (10), the first polymeric film layer (12) is formed of a polyester (e.g., PET) while the second polymeric film layer is formed of a fluoropolymer (e.g., PVF).

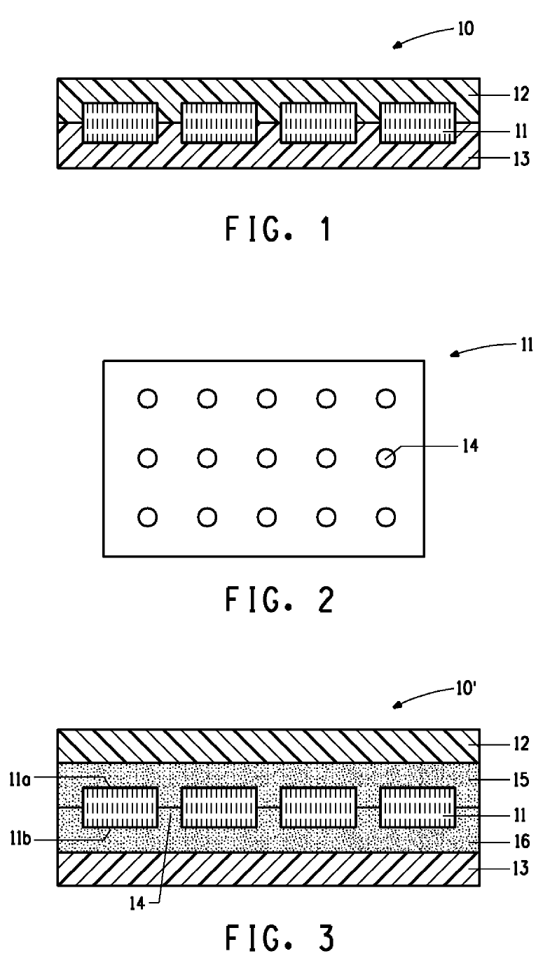

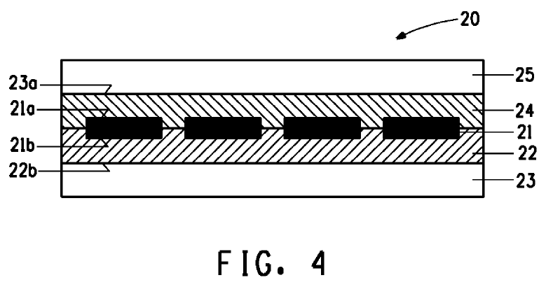

In a further embodiment of the laminated flame resistant sheet (10′, FIG. 3), there also may be a first adhesive layer (15) disposed between the perforated flame resistant sheet layer (11) and the first polymeric film layer (12) and/or a second adhesive layer (16) disposed between the perforated flame resistant sheet layer (11) and the second polymeric film layer (13). Suitable adhesives include, without limitation, reactive adhesives (e.g., polyurethane, acrylic, epoxy, polyimide, or silicone adhesives) and non-reactive adhesives (e.g., polyethylenes (including ethylene copolymers) or polyesters). Exemplary ethylene copolymers used herein as adhesives include, without limitation, ethylene-vinyl acetate copolymers (EVA), ethylene acrylate copolymers, and ethylene-maleic anhydride copolymers.

In one embodiment, the adhesives used herein are selected from polyurethane based adhesives and ethylene copolymer based adhesives.

Polyurethane based adhesives are well known within the art and may be obtained commercially from Mitsui Chemicals, Inc. (Japan) under the trade name Takenate™ or Dow Chemical Company (U.S.A.) under the trade name Mor-Free™.

Ethylene copolymer based adhesives are also well known within the art and commercially available. For example, Bynel® 2100 series resins, Bynel® 2200 series resins, Bynel® 3000 series resins, Bynel® 3100 series resins, and Bynel® 3800 series resins from DuPont may be used herein.

The adhesive layers (15, 16) may have a thickness of about 1-400 μm, or about 5-200 μm, or about 8-100 μm. In those embodiments where polyurethane based adhesives are used, the thickness of the adhesive layers (15, 16) may be about 1-100 μm, or about 8-50 μm, or about 8-30 μm, while in those embodiments wherein ethylene acrylate copolymer based adhesives are used, the thickness of the adhesive layers (15, 16) may be about 10-400 μm, or about 15-300 μm, or about 20-200 μm.

In accordance with the present disclosure, the laminated flame resistant sheet (10) disclosed herein may further comprise any other additional film or sheet layers, provided that the integrity and the flame resistant properties thereof is not negatively affected. Such other additional film or sheet layers may be selected from glass sheet layers, other additional polymeric film and/or sheet layers, and other additional flame resistant sheet layers (including additional layers of perforated flame resistant sheet layers).

The laminated flame resistant sheet (10) disclosed herein may be prepared by any lamination process. In one embodiment, the lamination process includes, positioning a perforated flame resistant sheet (11) between a first polymeric film (12) and a second polymeric film (13), and then subjecting the multi-layer structure to vacuum lamination at 120-170° C. and about 1 atm for about 8-30 minutes.

In those embodiments wherein the first and/or second adhesive layers (15, 16) are included in the laminated flame resistant sheet (10′), suitable adhesives may be first applied over the first and/or second polymeric film layers (12, 13) by any suitable methods before the multi-layer structure is prepared and subjected to lamination. For example, in one embodiment wherein polyurethane based adhesive is employed, the adhesive may be applied by solvent casting. In a further embodiment wherein ethylene acrylate copolymer based adhesives are employed, the adhesives may be applied by extrusion coating.

Also in accordance with the present disclosure, post the lamination process, at least portions of the apertures (14) of the perforated flame resistant sheet layer (11) are filled with polymeric material(s) of the first and/or second polymeric films (12, 13). In those embodiments wherein adhesive layer(s) (15, 16) are included, at least portions of the apertures (14) of the perforated flame resistant sheet layer (11) are filled with the adhesive materials comprised in the adhesive layers (15, 16). In one embodiment (FIG. 1), portions of the polymeric material comprised in the first polymeric film layer (12) are in contact and/or bonded with portions of the polymeric material comprised of the second polymeric film layer (13) via the apertures (14) in the perforated flame resistant sheet layer (11). In a further embodiment (FIG. 2), portions of the adhesive material in the first adhesive layer (15) are in contact and/or bonded with the adhesive material in the second adhesive layer (16) via the apertures (14) on the perforated flame resistant sheet layer (11).

As demonstrated by the examples below, laminated polymeric sheets without the flame resistant sheet layer often have poor flammability resistance (see e.g., CE1), while by including a flame resistant sheet layer between the polymeric film layers, the flammability resistance of the laminated sheet is very much improved (see e.g., CE2). However, as the flame resistant sheet layers often comprise high levels of flame retardant additives (e.g., inorganic particulates), the cohesive bonding strength of the flame resistant sheet itself is often too weak to maintain the integrity of the laminated sheet. It is found herein that when perforated flame resistant sheet layer is used (see e.g., E2), that the bonding integrity of the laminated sheet is improved, while the flammability resistance of the laminated sheet remains good.

Further disclosed herein is an article comprising the laminated flame resistant sheet (10) disclosed hereabove. The articles may include, without limitation, solar cell modules, roofs, building envelops, skylights, facades, and packaging films.

Yet further disclosed herein is a solar cell module (20, FIG. 4) comprising a solar cell layer (21) formed of one or a plurality of solar cells, a back encapsulant layer (22) laminated to a backside (21b) of the solar cell layer (21), and a backsheet (23) laminated to a backside (22b) of the back encapsulant layer (22), wherein the backsheet (23) is formed of the laminated flame resistant sheet disclosed above.

The solar cell(s) in the solar cell layer (21) may be any photoelectric conversion device that can convert solar radiation to electrical energy. They may be formed of photoelectric conversion bodies with electrodes formed on both main surfaces thereof. The photoelectric conversion bodies may be made of any suitable photoelectric conversion materials, such as, crystal silicon (c-Si), amorphous silicon (a-Si), microcrystalline silicon (μc-Si), cadmium telluride (CdTe), copper indium selenide (CuInSe₂ or CIS), copper indium/gallium diselenide (CuInₓGa₍₁₋ₓ₎Se₂ or CIGS), light absorbing dyes, and organic semiconductors. The front electrodes may be formed of conductive paste, such as silver paste, applied over the front surface of the photoelectric conversion body by any suitable printing process, such as screen printing or ink-jet printing. The front conductive paste may comprise a plurality of parallel conductive fingers and one or more conductive busbars perpendicular to and connecting the conductive fingers, while the back electrodes may be formed by printing metal paste over the entire back surface of the photoelectric conversion body. Suitable metals forming the back electrodes include, but are not limited to, aluminum, copper, silver, gold, nickel, cadmium, and alloys thereof.

When in use, the solar cell layer (21) typically has a front (or top) surface facing toward the solar radiation and a back (or bottom) surface facing away from the solar radiation. Therefore, each component layer within a solar cell module (20) has a front surface (or side) and a back surface (or side).

The solar cell modules (20) disclosed herein may further comprise a transparent front encapsulant layer (24) laminated to a front surface (21a) of the solar cell layer (21), and a transparent frontsheet (25) further laminated to a front surface (24a) of the front encapsulant layer (22).

Suitable materials used in forming the back encapsulant layer (22) and/or the transparent front encapsulant layer (24) include, without limitation, polyolefins, poly(vinyl butyral) (PVB), polyurethane (PU), polyvinylchloride (PVC), acid copolymers, silicone elastomers, epoxy resins, and the like. Suitable polyolefins used herein may include, without limitation, polyethylenes, ethylene vinyl acetates (EVA), ethylene acrylate copolymers (such as poly(ethylene-co-methyl acrylate) and poly(ethylene-co-butyl acrylate)), ionomers, polyolefin block elastomers, and the like. In one embodiment, the encapsulant layers (22, 24) are formed of EVA based compositions. Exemplary EVA based encapsulant materials can be commercially obtained from Bridgestone (Japan) under the trade name EVASKY™; Sanvic Inc. (Japan) under the trade name Ultrapearl™; Bixby International Corp (U.S.A.) under the trade name BixCure™; or RuiYang Photovoltaic Material Co. Ltd. (China) under the trade name Revax™. In a further embodiment, the encapsulant layers (22, 24) are formed of PVB based compositions. Exemplary PVB based encapsulant materials include, without limitation, DuPont™ PV5200 series encapsulant sheets. In a yet further embodiment, the encapsulant layers (22, 24) are formed of ionomer based compositions. Exemplary ionomer based encapsulant materials include, without limitation, DuPont™ PV5300 series encapsulant sheets and DuPont™ PV5400 series encapsulant sheets from DuPont

Any suitable glass or plastic sheets can be used as the transparent frontsheet (25). Suitable plastic materials comprised in the frontsheet (25) may include, without limitation, glass, polycarbonate, acrylics, polyacrylate, cyclic polyolefins, ethylene norbornene polymers, metallocene-catalyzed polystyrene, polyamides, polyesters, fluoropolymers and the like and combinations thereof.

Any suitable lamination process may be used to produce the solar cell modules (20) disclosed herein. In one embodiment, the process includes: (a) providing a plurality of electrically interconnected solar cells to form a solar cell layer (21); (b) forming a pre-lamination assembly wherein the solar cell layer (21) is laid over a back encapsulant layer (22), which is further laid over a backsheet (23), wherein the backsheet (23) is formed of the laminated flame resistant sheet disclosed hereabove; and (c) laminating the pre-lamination assembly under heat and pressure.

In a further embodiment, the process includes: (a) providing a plurality of electrically interconnected solar cells to form a solar cell layer (21); (b) forming a pre-lamination assembly wherein the solar cell layer (21) is sandwiched between a transparent front encapsulant layer (24) and a back encapsulant layer (22), which is further sandwiched between a transparent frontsheet (25) and a backsheet (23), wherein the backsheet (23) is formed of the laminated flame resistant sheet disclosed hereabove; and (c) laminating the pre-lamination assembly under heat and pressure.

In one embodiment, the lamination process is performed using a ICOLAM 10/08 laminator purchased from Meier Solar Solutions GmbH (Germany) at about 135° C.-150° C. and about 1 atm for about 10-25 minutes.

### EXAMPLES

### Material:

Glass Sheet (GS): 3.2 mm thick tempered glass purchased from Dongguan CSG Solar Glass Co., Ltd. (China);
EVA Sheet (EVA): Revax™ 767 ethylene vinyl acetate (EVA) sheet (500 μm thick) obtained from RuiYang Photovoltaic Material Co. Ltd. (China);
PET Film-1 (PET-1): Mylar® polyethylene terephthalate (PET) film (250 μm thick) obtained from DuPont Tiejin Films (USA);
PET Film-2 (PET-2): Mylar® polyethylene terephthalate (PET) film (100 μm thick) obtained from DuPont Tiejin Films (USA);
PVF Film (PVF): Tedlar® polyvinyl fluoride (PVF) film (25 μm thick) obtained from DuPont;
PU Adhesive (PU): a two-component polyurethane adhesive obtained from Mitsui Chemicals, Inc. (Japan), which is composed of Takelac™ PP-5430 and Takenate™ A-50 at a weight ratio of 1:1;
EA Adhesive (EA): Bynel® 22E757 ethylene acrylate copolymer resin obtained from DuPont.
Mica Sheet-1 (MS-1): Phlogopite mica sheet (125 μm thick and with grade name PJ5460-GD) obtained from Pamica Electric Material (Hubei) Co., Ltd. (China);
Mica Sheet-2 (MS-2): Phlogopite mica sheet (125 μm thick and with grade name PCM5460-G) obtained from Pamica Electric Material (Hubei) Co., Ltd. (China);
Mica Sheet-3 (MS-3): Calcined muscovite mica sheet (125 μm thick and with grade name PJ5460-G) obtained from Pamica Electric Material (Hubei) Co., Ltd. (China);
Perforated Mica Sheet-1 (PMS-1): obtained by die-cutting multiple apertures on a layer of MS-1. The multiple apertures each have a diameter of about 1 mm and are spaced about 7 mm apart;
Perforated Mica Sheet-2 (PMS-2): obtained by die-cutting multiple apertures on a layer of MS-1. The multiple apertures each have a diameter of about 1 mm and are spaced about 10 mm apart;
Perforated Mica Sheet-3 (PMS-3): obtained by die-cutting multiple apertures on a layer of MS-1. The multiple apertures each have a diameter of about 1.5 mm and are spaced about 10 mm apart;
Perforated Mica Sheet-4 (PMS-4): obtained by die-cutting multiple apertures on a layer of MS-1. The multiple apertures each have a diameter of about 2 mm and are spaced about 10 mm apart;
Perforated Mica Sheet-5 (PMS-5): obtained by forming multiple apertures on a layer of MS-1 using a sewing machine. The multiple apertures each have a diameter of about 0.3 mm and are spaced about 2.7 mm apart;
Perforated Mica Sheet-6 (PMS-6): obtained by die-cutting multiple apertures on a layer of MS-3. The multiple apertures each have a diameter of about 1 mm and are spaced about 10 mm apart;
Perforated Mica Sheet-7 (PMS-7): obtained by die-cutting multiple apertures on a layer of MS-3. The multiple apertures each have a diameter of about 1.5 mm and are spaced about 10 mm apart;
Perforated Mica Sheet-8 (PMS-8): obtained by die-cutting multiple apertures on a layer of MS-2. The multiple apertures each have a diameter of about 1 mm and are spaced about 10 mm apart;
Ceramic Fiber Sheet (CFS): ceramic fiber sheet (1 mm thick and with grade name JSGW-236) obtained from Jinshi High Temperature Materials Co, Ltd. (China);
Perforated Ceramic Fiber Sheet (PCFS): obtained by forming multiple apertures on a layer of the Ceramic Fiber Sheet (CFS) using a die-cutting method. The multiple apertures each have a diameter of about 1 mm and are spaced about 7 mm apart.
TPE Film (TPE): Solmate™ BTNE TPE backsheet obtained from Taiflex Scientific Co Ltd. (Taiwan), which has a tri-layer structure of “Tedlar® PVF2111 film/PET film/EVA sheet” (PVF/PET/EVA) with adhesive used between adjacent layers.

### Test Methods

Bonding Strength Test: The bonding strength of the laminated multi-layer sheets was determined following modified ASTM F88, wherein the sample width was set at 2.54 cm and the peeling speed at 12.7 cm/min.
Flammability Test: The flammability of the laminated multi-layer sheets was determined following Burning Test 1 or Burning Test 2. Burning Test 1 was the same as the Horizontal Burning Test outlined in Underwriters Laboratories UL94. Burning Test 2 includes, (a) placing a multi-layer sheet sample (10×7 cm) about 1 cm above a flame (with a temperature of >800° C.); (b) maintaining the sample above the flame with its polymer side down for 30 seconds; (c) rotating the sample 180° and maintaining the sample above the flame with its glass side down for 30 seconds; and (d) repeating steps (b) and (c) another two times.
Partial Discharge Test: Partial discharge tests were performed following ASTM D1868 at 23° C. and 50% relative humidity (50% RH) using a Partial Discharge Detector DDX 9101 from Hubbell Incorporated (USA).
Breakdown Voltage Test: Breakdown voltage tests were performed following ASTM D149 at 23° C. and 50% RH using a 700-D149-P series AC Dielectric Breakdown Tester from Hubbell Incorporated.
Water Vapor Transmission Rate (WVTR) Test: WVTR tests were performed following ASTM F1249 at 38° C., 100% RH, and a flow rate of 10 cc using a PERMATRAN-W™ Model 700 from Mocon Inc. (USA).

### Comparative Examples CE1-CE2 and Examples E1-E4

In CE1, a laminated tetra-layer sheet comprising a layer of PVF Film bonded to a layer of PET Film-1, which was further bonded to a layer of EVA Sheet, which was further bonded to a layer of Glass Sheet (with a dimension of 7×10 cm and denoted herein as “PVF/PET-1/EVA/GS”), was prepared as follows. First, a 40 μm thick coat of EA Adhesive was extrusion cast over a first surface of the PVF Film while an 80 μm thick coat of EA Adhesive and a 40 μm thick coat of EA Adhesive were extrusion cast over a first and a second surface of the PET Film-1, respectively. Thereafter, the coated PET Film-1 was placed between the PVF Film and the EVA Sheet with the coated first surface of the PVF film in contact with the coated first surface of the PET Film-1, and the Glass sheet was placed over the EVA Sheet. The as such obtained tetra-layer assembly was then vacuum laminated using a Meier ICOLAM™ 10/08 laminator (Meier Vakuumtechnik GmbH, Germany) at a pressure of 1 atm and a temperature of 145° C. for 15 minutes to form the final laminated tetra-layer sheet of “PVF/PET-1/EVA/GS”.

In CE2, a laminated penta-layer sheet having a structure similar to that of the laminated tetra-layer sheet of CE1 was provided, with the exception that a layer of Mica Sheet-1 was included and bonded between the PVF Film and the PET Film-1. The laminated penta-layer sheet of CE2, which is denoted herein as “PVF/MS-1/PET-1/EVA/GS” was prepared as follows. First, a 40 μm thick coat of EA Adhesive was extrusion cast on a first surface of the PVF Film and an 80 μm thick coat of EA Adhesive and a 40 μm thick coat of EA Adhesive were extrusion cast over a first and second surfaces of the PET Film-1, respectively. Then, Mica Sheet-1 was placed between the PVF Film and the PET Film-1 (with the first coated surface of the PVF Film and the first coated surface of the PET Film-1 in contact with Mica Sheet-1), the EVA Sheet was placed over the PET Film-1 and the Glass Sheet over the EVA Sheet to form a penta-layer structure. Thereafter, the penta-layer structure was vacuum laminated using a Meier Vakuumtechnick GMBG laminator under 1 atm and 145° C. for 15 minutes to form the final laminated penta-layer sheet of “PVF/MS-1/PET-1/EVA/GS”.

The laminated penta-layer sheet in E1 has a structure similar to that of the laminated penta-layer sheet of CE2, with the exception that a layer of Perforated Mica Sheet-1 was included and bonded between the PVF Film and the PET Film-1 in place of Mica Sheet-1. The laminated penta-layer sheet of E1 is denoted herein as “PVF/PMS-1/PET-1/EVA/GS”.

The laminated penta-layer sheet in E2 has a structure similar to that of the laminated penta-layer sheet of CE2, with the exception that a layer of Perforated Mica Sheet-2 was included and bonded between the PVF Film and the PET Film-1 in place of Mica Sheet-1. The laminated penta-layer sheet of E1 is denoted herein as “PVF/PMS-2/PET-1/EVA/GS”.

The laminated penta-layer sheet in E3 has a structure similar to that of the laminated penta-layer sheet of CE2, with the exception that a layer of Perforated Mica Sheet-3 was included and bonded between the PVF Film and the PET Film-1 in place of Mica Sheet-1. The laminated penta-layer sheet of E1 is denoted herein as “PVF/PMS-3/PET-1/EVA/GS”.

The laminated penta-layer sheet in E4 has a structure similar to that of the laminated penta-layer sheet of CE2, with the exception that a layer of Perforated Mica Sheet-4 was included and bonded between the PVF Film and the PET Film-1 in place of Mica Sheet-1. The laminated penta-layer sheet of E1 is denoted herein as “PVF/PMS-4/PET-1/EVA/GS”.

The laminated sheets in each of CE1-CE2 and E1-E4 prepared as such were then subject to bonding strength and flammability tests and the results are tabulated in Table 1.

As shown by Table 1, the laminated sheet made of polymers and glass (CE1) has very poor flammability. With the addition of a layer of mica sheet, the laminated sheet (CE2) had much improved flammability, but the bonding integrity thereof was decreased. However, by using perforated mica sheet, the laminated sheets (E1-E4), not only had excellent flammability, but also good bonding integrity. By the flammability data of E1-E4, it is also shown that the bonding integrity and the flammability of the final laminates were correlated with the size of the apertures on the perforated mica sheet. In general, the bigger the diameter of the apertures were, the higher were the bonding integrity of the final laminate and the poorer were the flammability of the final laminates.

TABLE 1

| | | | Perforation | | |
|---|---|---|---|---|---|
| | | | Specification | | |
| | | Flame | (Diameter/ | ¹Bonding | |
| | | Resistant | Distance) | Strength | |
| Samples | Structure | Sheet | (mm) | (N/cm) | ²Flammability |
| CE1 | PVF/PET-1/EVA/GS | — | — | 4.9 | Poor |
| CE2 | PVF/MS-1/PET-1/EVA/GS | MS-1 | — | 0.7 | Excellent |
| E1 | PVF/PMS-1/PET-1/EVA/GS | PMS-1 | 1/7 | 2.6 | Excellent |
| E2 | PVF/PMS-2/PET-1/EVA/GS | PMS-2 | 1/10 | 2.1 | Excellent |
| E3 | PVF/PMS-3/PET-1/EVA/GS | PMS-3 | 1.5/10 | 2.7 | Good |
| E4 | PVF/PMS-4/PET-1/EVA/GS | PMS-4 | 2/10 | 3 | Fair |

¹Bonding strength: 180° bonding strength between PVF Film and PET Film-1; when mica sheet was present, cohesive failure at the mica sheet layer was observed.
²Flammability: measured following Burning Test 2 described above; “Excellent” - none of the 3 samples was ignited and no polymer melt drops were observed in any of the 3 samples; “Good” - only 1 of 3 samples was ignited with the flame extinguished gradually after removal of the burner and no polymer melt drops were observed in any of the 3 samples; “Fair” - all 3 samples were ignited with the flame extinguished gradually after removal of the burner and polymer melt drops were observed in 1 out of 3 samples; and “Poor” - all 3 samples were ignited and the flame continued until all the polymeric materials were burned away in all 3 samples.

### Comparative Examples CE3-CE4 and Example E5

In CE3, a laminated tri-layer sheet comprising a layer of PET Film-1 bonded between a first layer of PVF Film and a second layer of PVF Film (which could be denoted as “PVF/PET-1/PVF” and had a dimension of 40×30 cm) was prepared as follows. First, using an automatic film applicator (model number 1133N and manufactured by Sheen Instruments Ltd., UK) a coat of PU Adhesive (about 45 μm thick) was cast over a first surface of the PET Film-1. After oven drying at 60° C. for 5 minutes the thickness of the dried PU Adhesive coat was reduced to about 15 μm. Then, the PET Film-1 was placed over the first PVF Film (with the coated first surface of the PET Film-1 in contact with the first PVF Film) and the resulting bi-layer structure was laminated on a Hot Roller Laminator (model number HL-100 and manufactured by Cheminstruments, USA) at room temperature under a pressure of 70 psi and a speed of 5 cm/sec. Thereafter, another coat of PU Adhesive was cast over a second surface of the PET Film-1 in the same way as described above. The second PVF Film was then placed over the coated second surface of the PET Film-1 and the resulting tri-layer structure was again laminated under the same conditions as above. The final laminated tri-layer sheet of “PVF/PET-1/PVF” was then obtained after oven drying at 60° C. for 5 days to allow the PU Adhesive to be cured.

The laminated tetra-layer sheet of CE4 has a structure similar to that of the laminated tri-layer sheet of CE3 with the exception that a layer of Mica Sheet-1 was bonded between the first PVF Film and the PET Film-1. The laminated tetra-layer sheet of CE4, which is denoted herein as “PVF/MS-1/PET-1/PVF”, was prepared as follows. First, using an automatic film application a coat of PU Adhesive (about 45 μm thick) was cast over a first surface of the PET Film-1. After oven drying at 60° C. for 5 minutes the thickness of the dried PU Adhesive coat was reduced to about 15 μm. Similarly, a coat of PU Adhesive was cast over one surface of the first PVF Film. Then, Mica Sheet-1 was placed between the first PVF Film and the PET Film-1 with the coated surfaces of the first PVF Film and the PET Film-1 in contact with Mica Sheet-1 and the resulting tri-layer structure was laminated on a hot roller laminator at room temperature under a pressure of 70 psi and a speed of 5 cm/sec. Thereafter, a coat of PU Adhesive was cast over a second surface of the PET Film-1 in the same way as described above. The second PVF Film was then placed over the coated second surface of the PET Film-1 and the resulting tetra-layer structure was again laminated under the same conditions as described above. The final laminated tetra-layer sheet of “PVF/MS-1/PET-1/PVF” was then obtained after oven drying at 60° C. for 5 days to allow the PU Adhesive to be cured.

The laminated tetra-layer sheet of E5 has a structure similar to that of the laminated tetra-layer sheet of CE4, with the exception that a layer of Perforated Mica Sheet-5 was used in place of Mica Sheet-1. The laminated tetra-layer sheet of E5 is denoted herein as “PVF/PMS-5/PET-1/PVF” and was prepared following the same process described above in CE4.

The laminated sheets in each of CE3-CE4 and E5 prepared as described were then subjected to bonding strength and flammability tests and the results are tabulated in Table 2.

Here again, it is demonstrated that the addition of perforated mica sheet improved the flammability of the laminated sheets while maintaining the bonding integrity thereof.

TABLE 2

| | | | | ²Flammability |
|---|---|---|---|---|
| | | | | (Flame |
| | | Flame | ¹Bonding | spreading |
| | | Resistant | Strength | speed) |
| Samples | Structure | Sheet | (N/cm) | (mm/min) |
| CE3 | PVF/PET-1/PVF | — | ³ND | 74 |
| CE4 | PVF/MS-1/PET-1/PVF | MS-1 | 0.7 | ³ND |
| E5 | PVF/PMS-5/PET- | PMS-5 | 2.2 | 39 |
| | 1/PVF | | | |

¹Bonding strength: The bonding strength between the first PVF Film and the PET Film-1; when mica sheet was present, cohesive failure at the mica sheet layer was observed.
²Flammability: Measured following Burning Test 1.
³ND: Not Determined.

### Comparative Example CE5 and Example E6

The laminated tri-layer sheet of CE5 (210×297 mm) had a structure similar to that of the laminated tri-layer sheet of CE3 with the exception that EA Adhesive was used instead of the PU Adhesive. The laminated tri-layer sheet of CE5, which is also denoted herein as “PVF/PET-1/PVF”, was prepared as follows. First, a 40 μm thick coat of EA Adhesive was extrusion cast over a first surface of the first PVF Film, while a 80 μm thick coat of EA Adhesive and a 40 μm thick coat of EA Adhesive were extrusion cast over a first and a second surface of the PET Film-1, respectively. Thereafter, the PET Film-1 was placed between the two PVF Films with the coated first surface of the first PVF film in contact with the coated first surface of the PET Film-1. The resulting tri-layer structure was vacuum laminated using a Meier ICOLAM™ 10/08 laminator at a pressure of 1 atm and temperature of 145° C. for 15 min to form the final laminated tri-layer sheet of “PVF/PET-1/PVF”.

The laminated tetra-layer sheet of E6 had a structure similar to that of the laminated tri-layer sheet of CE5, with the exception that a layer of Perforated Ceramic Fiber Sheet (PCFS) was bonded between the first PVF Film and the PET Film-1. The laminated tetra-layer sheet of E6 is denoted herein as “PVF/PCFS/PET-1/PVF” and was prepared following the same process described above in CE5.

The laminated sheets in each of CE5 and E6 prepared as described were then subjected to flammability tests and the results are tabulated in Table 3.

It is demonstrated herein that the addition of perforated ceramic fiber sheet improved the flammability of the laminated sheets.

TABLE 3

| | | Flame | ¹Flammability |
|---|---|---|---|
| | | Resistant | (Flame spreading speed) |
| Samples | Structure | Sheet | (mm/min) |
| CE5 | PVF/PET-1/PVF | — | 51 |
| E6 | PVF/PCFS/PET-1/PVF | PCFS | 21 |

¹Flammability: Measured following Burning Test 1.

### Comparative Example CE6 and Example E7

The laminated penta-layer sheet of CE6 had a similar structure to that of the laminated penta-layer sheet of CE2 with the exception that a layer of Ceramic Fiber Sheet was included and bonded between the PVF Film and the PET Film-1 in place of Mica Sheet-1. The laminated penta-layer sheet of CE6 is denoted herein as “PVF/CFS/PET-1/EVA/GS”.

The laminated penta-layer sheet of E7 had a structure similar to that of the laminated penta-layer sheet of CE6, with the exception that a layer of Perforated Ceramic Fiber Sheet was used in place of the Ceramic Fiber Sheet. The laminated penta-layer sheet of E7 is denoted herein as “PVF/PCFS/PET-1/EVA/GS”.

The laminated sheets in each of CE6 and E7 prepared as described were then subjected to bonding strength and flammability tests and the results are tabulated in Table 4.

It is demonstrated that the addition of perforated ceramic fiber sheet improved the bonding integrity of the laminated sheets.

TABLE 4

| | | Flame | ¹Bonding |
|---|---|---|---|
| | | Resistant | Strength |
| Samples | Structure | Sheet | (N/cm) |
| CE6 | PVF/CFP/PET-1/EVA/GS | CFS | ²0 |
| E7 | PVF/PCFP/PET-1/EVA/GS | PCFS | 1.3 |

¹Bonding strength: The bonding strength between the first PVF Film and the PET Film-1; cohesive failure at the mica sheet layer was observed.
²0: Too weak to be measurable.

### Comparative Example CE7 and Examples E8-E10

The tri-layer TPE Film used in CE7 is a solar cell backsheet obtained from Taiflex Scientific Co Ltd. under a trade name of Somate® BTNE.

In each of E8-10, a laminated tri-layer sheet (structure detailed in Table 5, with 50 μm thick EA Adhesive layers included between each pair of adjacent film or sheet layers) was prepared following the same procedure described above in CE2 without the addition of the EVA Sheet and the Glass Sheet.

The laminated multi-layer sheets in CE7 and E8-E9 were then subject to partial discharge test, breakdown voltage test, and water vapor transmission rate (WVTR) test. Results are tabulated in Table 5 below. It is demonstrated that the laminated sheets including perforated mica sheets had a partial discharge, breakdown voltage, and water vapor transmission rate (WVTR) comparable to that of prior TPE solar cell backsheets.

TABLE 5

| | | Partial | Breakdown | |
|---|---|---|---|---|
| | | Discharge | Voltage | WVTR |
| Samples | Structure | (kV) | (kV) | (gm/m²-day |
| CE7 | Somate ® BTNE | 1.216 | 24.22 | 3.44 |
| | PTE film | | | |
| E8 | PVF/PMS-6/PET-2 | 1.7114 | 20.5 | 2.2 |
| E9 | PVF/PMS-7/PET-2 | 1.6678 | 20.6 | 2.4 |
| E10 | PVF/PMS-8/PET-2 | 1.6952 | 19.4 | 1.9 |

What is claimed is:

1. A laminated flame resistant sheet comprising a first and a second polymeric film layer and a perforated flame resistant sheet layer laminated between the first and the second polymeric film layer, wherein, the perforated flame resistant sheet layer is formed of a sheet that is not ignitable following UL 94 horizontal burning test and comprises multiple apertures throughout, and wherein each of the apertures has an average diameter of 0.1-8 mm and are spaced 1-50 mm apart from adjacent apertures.

2. The laminated flame resistant sheet of claim 1, wherein the perforated flame resistant sheet layer is formed of a composition comprising 40 wt % or more (based on the total weight of the composition) of inorganic particulates selected from the group consisting of crystallized mineral silicate platelets, ceramic fibers, alumina powders, gibbsite powders, asbestos fibers, glass fibers, and combinations of two or more thereof.

3. The laminated flame resistant sheet of claim 2, wherein the inorganic particulates are selected from the group consisting of crystallized mineral silicate platelets.

4. The laminated flame resistant sheet of claim 3, wherein the crystallized mineral silicate platelets are selected from the group consisting of particles of mica, vermiculite, calcined clay, silica, talc, wollastonite, and combinations of two or more thereof.

5. The laminated flame resistant sheet of claim 2, wherein the inorganic particulates are selected from ceramic fibers.

6. The laminated flame resistant sheet of claim 2, wherein the composition that forms the perforated flame resistant sheet layer comprises 60 wt % or more of the inorganic particulates.

7. The laminated flame resistant sheet of claim 1, wherein each of the apertures has an average diameter of 0.3-5 mm and are spaced 1-30 mm apart from adjacent apertures.

8. The laminated flame resistant sheet of claim 1, wherein each of the first and second polymeric film layers is independently formed of a composition comprising a polymeric material selected from the group consisting of fluoropolymers, polyesters, polycarbonates, polyolefins ethylene copolymers, polyvinyl butyrals, norbornenes, polystyrenes, styrene-acrylate copolymers, acrylonitrile-styrene copolymers, polyacrylates, polyethersulfones, polysulfones, polyamides, polyurethanes, acrylics, cellulose acetates, cellulose triacetates, cellophanes, polyvinyl chlorides, vinylidene chloride copolymers, epoxy, and combinations of two or more thereof.

9. The laminated flame resistant sheet of claim 8, wherein each of the first and second polymeric film layers is independently formed of a composition comprising a fluoropolymer or a polyester.

10. The laminated flame resistant sheet of claim 9, wherein the fluoropolymer is selected from the group consisting of homopolymers and copolymers of vinyl fluorides (VF), vinylidene fluorides (VDF), tetrafluoroethylenes (TFE), hexafluoropropylenes (HFP), chlorotrifluoroethlyenes (CTFE), and combinations of two or more thereof; or preferably the fluoropolymer is selected from the group consisting of polyvinyl fluorides (PVF), polyvinylidene fluorides (PVDF), ethylene chlorotrifluoroethlyene copolymers (ECTFE), ethylene tetrafluoroethylene copolymers (ETFE), and combinations of two or more thereof.

11. The laminated flame resistant sheet of claim 9, wherein the polyester is selected from the group consisting of polyethylene terephthalate (PET), polybutylene terephthalate (PBT), polyethylene trimethylene terephthalate (PTT), polyethylene naphthalates (PEN), and combinations of two or more thereof.

12. The laminated flame resistant sheet of claim 9, wherein the first polymeric film layer is formed of a composition comprising a fluoropolymer and the second polymeric film layer is formed of a composition comprising a polyester, and wherein the fluoropolymer is PVF and the polyester is PET.

13. The laminated flame resistant sheet of claim 1, which further comprises a first adhesive layer disposed between the perforated flame resistant sheet layer and the first polymeric film layer and/or a second adhesive layer disposed between the perforated flame resistant sheet layer and the second polymeric film layer.

14. The laminated flame resistant sheet of claim 13, wherein each of first and second adhesive layers is independently formed of an adhesive material selected from the group consisting of reactive adhesives and non-reactive adhesives.

15. The laminated flame resistant sheet of claim 14, wherein the first and second adhesive layer is independently formed of an adhesive material selected from polyurethanes and ethylene copolymers.

16. The laminated flame resistant sheet of claim 1, which further comprises other additional film or sheet layers.

17. An article comprising the laminated flame resistant sheet of claim 1.

18. The article of claim 16, which is selected from the group consisting of solar cell modules, roofs, building envelops, skylights, facades, and packaging films.

19. A solar cell module comprising a solar cell layer formed of one or a plurality of solar cells, a back encapsulant layer laminated to a back side of the solar cell layer, and a backsheet laminated to a backside of the back encapsulant layer, wherein the backsheet is formed of the laminated flame resistant sheet recited in claim 1.

20. The solar cell module of claim 19, wherein the backsheet is formed of the laminated flame resistant sheet recited in claim 12, and wherein the first polymeric film layer of the laminated flame resistant sheet recited in claim 12 is positioned to form an outermost layer of the solar cell module.
